(19) United States
(12) Patent Application Publication
(10) Pub. No.: US 2022/0293030 A1
(43) Pub. Date: Sep. 15, 2022

(54) DISPLAY PANEL, DISPLAY DEVICE, AND CONTROL METHOD OF DISPLAY DEVICE

(71) Applicant: BOE Technology Group Co., Ltd., Beijing (CN)

(72) Inventors: Haidong WU, Beijing (CN); Yansong LI, Beijing (CN); Guanyin WEN, Beijing (CN); Xiaobo DU, Beijing (CN); Bei WANG, Beijing (CN)

(21) Appl. No.: 17/513,641

(22) Filed: Oct. 28, 2021

(30) Foreign Application Priority Data
Mar. 9, 2021 (CN) 202110252865.7

(51) Int. Cl. G09G 3/20; G09G 3/3208

(52) U.S. Cl. CPC G09G 3/2003; G09G 3/3208; G09G 2320/0242; G09G 2300/0443; G09G 2300/0452; G09G 2300/0465

(57) ABSTRACT

The present disclosure discloses a display panel, a display device, and a control method of the display device. The display panel includes sub-pixels of a plurality of colors, wherein the sub-pixels of the plurality of colors include first blue sub-pixels and second blue sub-pixels, and a wavelength of each first blue sub-pixel is smaller than a wavelength of each second blue sub-pixel. The first blue sub-pixels and the second blue sub-pixels are driven to perform image display when the display panel is in a regular display mode; and the second blue sub-pixels are driven to perform image display when the display panel is in an eye protection display mode.

### CROSS REFERENCE TO RELATED APPLICATIONS

The present disclosure claims priority to Chinese Patent Application No. 202110252865.7 filed with the China National Intellectual Property Administration on Mar. 9, 2021, the entire contents of which are incorporated herein by its reference.

### FIELD

The present disclosure relates to the field of display technology, in particular to a display panel, a display device, and a control method of the display device.

### BACKGROUND

Compared with a liquid crystal display (LCD), an organic light-emitting diode (OLED) display device has the advantages of high color saturation, light weight, thinness, and flexibility, and has attracted great attention in the field of display and lighting.

### SUMMARY

Embodiments of the present disclosure provide a display panel, a display device, and a control method of the display device, which can be switched between a regular display mode and an eye protection display mode.

In a first aspect, an embodiment of the present disclosure provides a display panel, including: sub-pixels of a plurality of colors; wherein the sub-pixels of the plurality of colors include first blue sub-pixels and second blue sub-pixels; and a wavelength of each of the first blue sub-pixels is smaller than a wavelength of each of the second blue sub-pixels; the first blue sub-pixels and the second blue sub-pixels are driven to perform image display when the display panel is in a regular display mode; and the second blue sub-pixels are driven to perform image display when the display panel is in an eye protection display mode.

In some embodiments of the present disclosure, the wavelength of each first blue sub-pixel is 440-455 nm and the wavelength of each second blue sub-pixel is 455-480 nm.

In some embodiments of the present disclosure, a display brightness of the second blue sub-pixel in the eye protection display mode is greater than a display brightness of the second blue sub-pixel in the regular display mode.

In some embodiments of the present disclosure, the display brightness of the second blue sub-pixel in the eye protection display mode is 2 times the display brightness of the second blue sub-pixel in the regular display mode.

In some embodiments of the present disclosure, the sub-pixels of the plurality of colors further include red sub-pixels and green sub-pixels.

In some embodiments of the present disclosure, the first blue sub-pixels and the red sub-pixels are alternately arranged in a first direction to form first pixel rows; the second blue sub-pixels and the red sub-pixels are alternately arranged in the first direction to form second pixel rows; the first pixel rows and the second pixel rows are alternately arranged in a second direction; and the first direction and the second direction intersect; the first blue sub-pixels and the red sub-pixels are alternately arranged in the second direction to form first pixel columns; the second blue sub-pixels and the red sub-pixels are alternately arranged in the second direction to form second pixel columns; and the first pixel columns and the second pixel columns are alternately arranged in the first direction; and one green sub-pixel is at a center of a quadrilateral formed by four sub-pixels in two adjacent rows and two adjacent columns.

In some embodiments of the present disclosure, each of the first blue sub-pixels and each of the second blue sub-pixels are the same in shape and size, an area of each of the red sub-pixels is smaller than an area of the first blue sub-pixel, and an area of each of the green sub-pixels is the smallest.

In some embodiments of the present disclosure, a shape of each of the first blue sub-pixels, the second blue sub-pixels, the red sub-pixels and the green sub-pixels is a square, a rectangle, a diamond, or a circle.

In some embodiments of the present disclosure, the first blue sub-pixels and the second blue sub-pixels are alternately arranged in a first direction to form a plurality of pixel rows; the first blue sub-pixels and the second blue sub-pixels are alternately arranged in a second direction to form a plurality of pixel columns; and the first direction and the second direction intersect; in each pixel row, one red sub-pixel is between a first blue sub-pixel and a second blue sub-pixel adjacent to each other; and in each of the pixel columns, one red sub-pixel is between a first blue sub-pixel and a second blue sub-pixel adjacent to each other; and one green sub-pixel is at a center of a quadrilateral formed by four sub-pixels in two adjacent rows and two adjacent columns.

In some embodiments of the present disclosure, each of the first blue sub-pixels and each of the second blue sub-pixels are the same in shape and size, an area of each of the red sub-pixels is smaller than an area of the first blue sub-pixel, and an area of each of the green sub-pixels is the smallest.

In some embodiments of the present disclosure, a shape of each of the first blue sub-pixels, the second blue sub-pixels, the red sub-pixels and the green sub-pixels is a square, a rectangle, a diamond, or a circle.

In some embodiments of the present disclosure, one red sub-pixel, one green sub-pixel, and one first blue sub-pixel constitute a first pixel; and one red sub-pixel, one green sub-pixel, and one second blue sub-pixel constitute a second pixel; and first pixels and second pixels are alternately arranged in a first direction, and the first pixels and the second pixels are alternately arranged in a second direction; and the first direction and the second direction intersect.

In some embodiments of the present disclosure, the first blue sub-pixels, the second blue sub-pixels, the red sub-pixels, and the green sub-pixels are the same in size.

In some embodiments of the present disclosure, one red sub-pixel, one green sub-pixel, and one first blue sub-pixel constitute a first pixel; and the one green sub-pixel and the one red sub-pixel in the first pixel are arranged along one side of the first blue sub-pixel in the first pixel; one red sub-pixel, one green sub-pixel, and one second blue sub-pixel constitute a second pixel; and the one green sub-pixel and the one red sub-pixel in the second pixel are arranged along one side of the second blue sub-pixel in the second pixel; and first pixels and second pixels are alternately arranged in a first direction, and the first pixels and the second pixels are alternately arranged in a second direction; and the first direction and the second direction intersect.

In some embodiments of the present disclosure, a size of the first blue sub-pixel and a size of the second blue sub-pixel are the same, a size of the red sub-pixel in the first pixel and a size of the green sub-pixel in the first pixel are smaller than the size of the first blue sub-pixel in the first pixel, and a size of the red sub-pixel in the second pixel and a size of the green sub-pixel in the second pixel are smaller than the size of the second blue sub-pixel in the second pixel.

In some embodiments of the present disclosure, the display panel is an organic light-emitting diode display panel.

In a second aspect, an embodiment of the present disclosure provides a display device, including any one of the display panels described above.

In a third aspect, an embodiment of the present disclosure provides a control method of the display device, including: driving the first blue sub-pixels and the second blue sub-pixels to perform image display when the display device is in a regular display mode; and driving the second blue sub-pixels to perform image display when the display device is in an eye protection display mode.

In some embodiments of the present disclosure, a display brightness of the second blue sub-pixel in the eye protection display mode is greater than a display brightness of the second blue sub-pixel in the regular display mode.

In some embodiments of the present disclosure, the display brightness of the second blue sub-pixel in the eye protection display mode is 2 times the display brightness of the second blue sub-pixel in the regular display mode.

### BRIEF DESCRIPTION OF THE DRAWINGS

In order to more clearly illustrate the technical solutions of the embodiments of the present disclosure, the drawings required to be used in the embodiments of the present disclosure will be briefly described below, and it will be apparent that the drawings described below are merely some embodiments of the present disclosure and that other drawings can be derived from these drawings without inventive labor for those of ordinary skill in the art.

FIG. 1 is a first partial top view of a display panel provided by an embodiment of the present disclosure.

FIG. 2 is a second partial top view of the display panel provided by the embodiment of the present disclosure.

FIG. 3 is a third partial top view of the display panel provided by the embodiment of the present disclosure.

FIG. 4 is a fourth partial top view of the display panel provided by the embodiment of the present disclosure.

FIG. 5 is a flow diagram of a control method of a display device provided by an embodiment of the present disclosure.

Wherein, 10—first blue sub-pixel, 11—second blue sub-pixel, 12—red sub-pixel, 13—green sub-pixel, E—first pixel row, F—second pixel row, M—first pixel column, N—second pixel column, P1—first pixel, P2—second pixel.

### DETAILED DESCRIPTION OF THE EMBODIMENTS

In order to make the above objects, features and advantages of the present disclosure more obvious and easy to understand, the present disclosure will be further described below in combination with the accompanying drawings and embodiments. However, the example embodiments can be implemented in a variety of forms and should not be understood to be limited to the embodiments set forth herein; and on the contrary, providing these embodiments makes the present disclosure more comprehensive and complete, and comprehensively conveys the concept of the example embodiments to those skilled in the art. The same reference signs denote the same or similar structures in the drawings, and thus repeated description thereof will be omitted. The words expressing the position and direction described in the present disclosure are explained by taking the drawings as an example, but changes can also be made according to needs, and all the changes are included in the protection scope of the present disclosure. The drawings of the present disclosure are only used to illustrate the relative position relationship and do not represent the real scale.

Compared with a liquid crystal display (LCD), an organic light-emitting diode (OLED) display device has the advantages of high color saturation, light weight, thinness, and flexibility, and has attracted great attention in the field of display and lighting.

At present, the display device usually includes three kinds of pixels, namely red pixels, green pixels and blue pixels. In order to improve the color saturation of the display, the blue pixels pursue dark blue luminescence, and the red pixels pursue dark red luminescence. However, when the wavelength of dark blue light is less than 450 nm, the damage to the human eyes is greater, and it is easy to cause eye fatigue. Therefore, more and more users begin to pay attention to the eye protection needs of the display device.

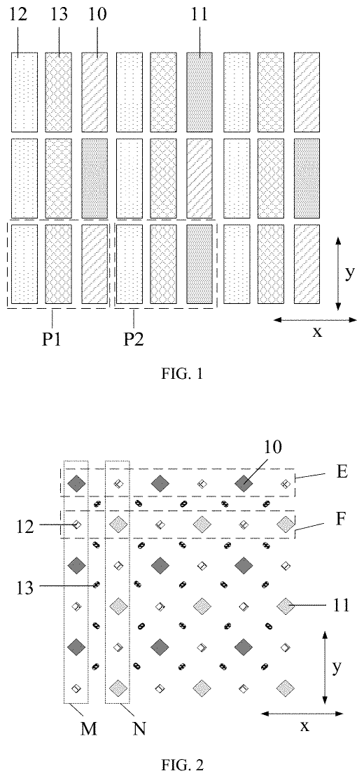

In view of this, as shown in FIG. 1, a display panel provided by an embodiment of the present disclosure includes sub-pixels of a plurality of colors, wherein the sub-pixels of the plurality of colors includes first blue sub-pixels 10 and second blue sub-pixels 11, and a wavelength of each first blue sub-pixel 10 is smaller than a wavelength of each second blue sub-pixel 11.

When the first blue sub-pixels 10 are used for image display, the blue saturation of the display screen can be increased, and when the second blue sub-pixels 11 are used for image display, the damage to human eyes can be avoided.

Therefore, in the embodiments of the present disclosure, when the display panel is in the regular display mode, the first blue sub-pixels 10 and the second blue sub-pixels 11 are driven to perform image display; and when the display panel is in the eye protection display mode, the second blue sub-pixels 11 are driven to perform image display.

Since the wavelength of each second blue sub-pixel 11 is greater than the wavelength of each first blue sub-pixel 10, when the display panel is in the regular display mode, simultaneously driving the first blue sub-pixels 10 and the second blue sub-pixels 11 can increase the saturation of blue color. When the display panel is in the eye protection display mode, and only the second blue sub-pixels that are non-irritating to the human eyes are driven to perform image display, eye fatigue can be mitigated. The user can freely switch the display modes according to the use requirements.

In some embodiments, the light-emitting wavelength of each first blue sub-pixel 10 is 440-455 nm. Each first blue sub-pixel 10 has a narrow half width peak and thus has high saturation, and using the second blue sub-pixels 10 for image display is conducive to improving the display color gamut.

The light-emitting wavelength of each second blue sub-pixel 11 is 455-480 nm, and since wavelengths of 450 nm or below are more irritating to the human eyes, using the second blue sub-pixels 11 for image display can protect eyes and relieve eye fatigue.

Since the first blue sub-pixels 10 and the second blue sub-pixels 11 emit light at the same time in the regular display mode, while only the second blue sub-pixels 11 emit light in the eye protection display mode, in order to make the display brightness difference between the two display modes be within the preset range, the display brightness of each second blue sub-pixel 11 in the eye protection display mode is set to be greater than the display brightness of the second blue sub-pixel 11 in the regular display mode in the embodiments of the present disclosure.

In a practical application, the number of the first blue sub-pixels 10 and the number of the second blue sub-pixels 11 may be set to be equal, at this time, the display brightness of each second blue sub-pixel 11 in the eye protection display mode may be set to be 2 times the display brightness of the second blue sub-pixel 11 in the regular display mode.

In order to achieve color image display, referring to FIG. 1, the display panel further includes red sub-pixels 12 and green sub-pixels 13.

The sub-pixels of the plurality of colors can be arranged in a variety of ways.

In some embodiments, as shown in FIG. 1, one red sub-pixel 12, one green sub-pixel 13, and one first blue sub-pixel 10 constitute a first pixel P1; one red sub-pixel 12, one green sub-pixel 13, and one second blue sub-pixel 11 constitute a second pixel P2; the first pixels P1 and the second pixels P2 are alternately arranged in a first direction x, and the first pixels P1 and the second pixels P2 are alternately arranged in a second direction y; wherein the first direction x and the second direction y intersect, the first direction x may be in the manner of pixel rows, the second direction y may be in the manner of pixel columns, and the first direction x and the second direction y may be perpendicular to each other.

The pixel arrangement structure shown in FIG. 1 is a conventional pixel arrangement, and the first blue sub-pixels 10, the second blue sub-pixels 11, the red sub-pixels 12, and the green sub-pixels 13 are each the same in shape and size. The graphic design of a mask is relatively simple with conventional pixel arrangement.

According to some embodiments of the present disclosure, two kinds of pixels, namely first pixels P1 including first blue sub-pixels 10 and second pixels P2 including second blue sub-pixels 11, are provided. By alternately arranging the first pixels P1 and the second pixels P2 in the first direction x and the second direction y, respectively, the first blue sub-pixels P1 and the second blue sub-pixels P2 can be evenly distributed in the entire display area to avoid the problem of missing blue in certain locations in the eye protection display mode.

In some embodiments of the present disclosure, the first blue sub-pixels 10, the second blue sub-pixels 11, the red sub-pixels 12, and the green sub-pixels 13 are the same in size and shape, and may be of a simple square or rectangle, which is not limited here.

When the display panel is in the regular display mode, the first blue sub-pixels 10 and the second blue sub-pixels 11 are driven to perform image display; and when the display panel is in the eye protection display mode, the second blue sub-pixels 11 are driven to perform image display, and the user can freely adjust the display mode according to the use requirements.

FIG. 2 is a second partial top view of the display panel provided by the embodiment of the present disclosure.

In some embodiments, referring to FIG. 2, the display panel includes first blue sub-pixels 10, second blue sub-pixels 11, red sub-pixels 12, and green sub-pixels 13.

In some embodiments, the first blue sub-pixels 10 and the red sub-pixels 12 are alternately arranged in the first direction x to form first pixel rows E, the second blue sub-pixels 11 and the red sub-pixels 12 are alternately arranged in the first direction x to form second pixel rows F, and the first pixel rows E and the second pixel rows F are alternately arranged in the second direction y, wherein the first direction x and the second direction y intersect.

The first blue sub-pixels 10 and the red sub-pixels 12 are alternately arranged in the second direction y to form first pixel columns M, the second blue sub-pixels 11 and the red sub-pixels 12 are alternately arranged in the second direction y to form second pixel columns N, and the first pixel columns M and the second pixel columns N are alternately arranged in the first direction x.

One green sub-pixel 13 is arranged at the center of a quadrilateral formed by four sub-pixels in two adjacent rows and two adjacent columns.

Compared with the traditional arrangement mode in which the number of red, green and blue sub-pixels is 1:1:1, the above-mentioned arrangement mode of the sub-pixels has the advantages that the total number of the sub-pixels is reduced by one third, so more sub-pixels can be arranged in a limited space, which is conducive to improving the display ppi. And the number of the green sub-pixels 13 is 2 times the number of the red sub-pixels 12, since the brightness of the green sub-pixels 13 is relatively high, providing more green sub-pixels 13 is advantageous in boosting the overall brightness of the display panel.

In the embodiments of the present disclosure, the first blue sub-pixels 10 and the second blue sub-pixels 11 are the same in shape and size, the area of each red sub-pixel 12 is smaller than the area of each first blue sub-pixel 10, and the area of each green sub-pixel 13 is the smallest. Since blue sub-pixels have low luminous efficiency and relatively short lifetime, the size of the first blue sub-pixels 10 and the size of the second blue sub-pixels 11 are set to be large, and the service life of the first blue sub-pixels 10 and the service life of the second blue sub-pixels 11 can be prolonged, which is conducive to balancing the service life between sub-pixels.

In the embodiments of the present disclosure, the shapes of the first blue sub-pixels 10, the second blue sub-pixels 11, the red sub-pixels 12, and the green sub-pixels 13 may be a pattern such as a square, a rectangle, a diamond, or a circle, which are not limited here.

When the display panel is in the regular display mode, the first blue sub-pixels 10 and the second blue sub-pixels 11 are driven to perform image display; when the display panel is in the eye protection display mode, the second blue sub-pixels 11 are driven to perform image display, and the user can freely adjust the display mode according to the use requirements.

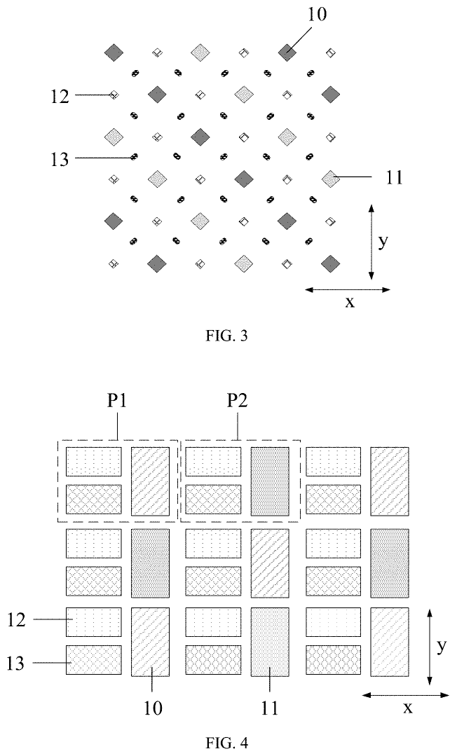

FIG. 3 is a third partial top view of the display panel provided by the embodiment of the present disclosure.

In some embodiments, referring to FIG. 3, the display panel includes first blue sub-pixels 10, second blue sub-pixels 11, red sub-pixels 12, and green sub-pixels 13.

In some embodiments, the first blue sub-pixels 10 and the second blue sub-pixels 11 are alternately arranged in the first direction x to form a plurality of pixel rows; the first blue sub-pixels 10 and the second blue sub-pixels 11 are alternately arranged in the second direction y to form a plurality of pixel columns; and the first direction x and the second direction y intersect.

In each pixel row, one red sub-pixel 12 is arranged between the adjacent first blue sub-pixel 10 and second blue sub-pixel 11; and in each pixel column, one red sub-pixel 12 is arranged between the adjacent first blue sub-pixel 10 and second blue sub-pixel 11.

One green sub-pixel 13 is arranged at the center of a quadrilateral formed by four sub-pixels in two adjacent rows and two adjacent columns.

Compared with the traditional arrangement mode in which the number of red, green and blue sub-pixels is 1:1:1, the above-mentioned arrangement mode of the sub-pixels has the advantages that the total number of the sub-pixels is reduced by one third, so more sub-pixels can be arranged in a limited space, which is conducive to improving the display ppi. And the number of the green sub-pixels 13 is 2 times the number of the red sub-pixels 12, since the brightness of the green sub-pixels 13 is relatively high, providing more green sub-pixels 13 is advantageous in boosting the overall brightness of the display panel.

The first blue sub-pixels 10 and the second blue sub-pixels 11 are uniformly arranged in the display area, which is more conducive to image display.

In the embodiments of the present disclosure, the first blue sub-pixels 10 and the second blue sub-pixels 11 are the same in shape and size, the area of each red sub-pixel 12 is smaller than the area of each first blue sub-pixel 10, and the area of each green sub-pixel 13 is the smallest. Since blue sub-pixels have low luminous efficiency and relatively short lifetime, the size of the first blue sub-pixels 10 and the size of the second blue sub-pixels 11 are set to be large, and the service life of the first blue sub-pixels 10 and the service life of the second blue sub-pixels 11 can be prolonged, which is conducive to balancing the service life between sub-pixels.

In the embodiments of the present disclosure, the shapes of the first blue sub-pixels 10, the second blue sub-pixels 11, the red sub-pixels 12, and the green sub-pixels 13 may be a pattern such as a square, a rectangle, a diamond, or a circle, which are not limited here.

When the display panel is in the regular display mode, the first blue sub-pixels 10 and the second blue sub-pixels 11 are driven to perform image display; when the display panel is in the eye protection display mode, the second blue sub-pixels 11 are driven to perform image display, and the user can freely adjust the display mode according to the use requirements.

FIG. 4 is a fourth partial top view of the display panel provided by the embodiment of the present disclosure.

In another implementable manner, referring to FIG. 4, the display panel includes first blue sub-pixels 10, second blue sub-pixels 11, red sub-pixels 12, and green sub-pixels 13.

In some embodiments, one red sub-pixel 12, one green sub-pixel 13, and one first blue sub-pixel 10 constitute a first pixel P1, and the one green sub-pixel 13 and the one red sub-pixel 12 in the first pixel P1 are arranged along one side of the first blue sub-pixel 10 in the first pixel P1.

One red sub-pixel 12, one green sub-pixel 13, and one second blue sub-pixel 11 constitute a second pixel P2, and the one green sub-pixel 13 and the one red sub-pixel 12 in the second pixel P2 are arranged along one side of the second blue sub-pixel 11 in the second pixel P2.

The first pixels P1 and the second pixels P2 are alternately arranged in the first direction x, and the first pixels P1 and the second pixels P2 are alternately arranged in the second direction y; and the first direction x and the second direction y intersect.

An embodiment of the present disclosure provides two kinds of pixels, namely first pixels P1 including first blue sub-pixels 10 and second pixels P2 including second blue sub-pixels 11. By alternately arranging the first pixels P1 and the second pixels P2 in the first direction x and the second direction y, respectively, the first blue sub-pixels P1 and the second blue sub-pixels P2 can be evenly distributed in the entire display area to avoid the problem of missing blue in certain locations in the eye protection display mode.

With the above pixel arrangement, the size of the first blue sub-pixels 10 and the size of the second blue sub-pixels 11 can be the same, while the size of the red sub-pixels 12 in the first pixels P1 and the size of the green sub-pixels in the first pixels P1 are smaller than that of the first blue sub-pixels 10 in the first pixels P1, and the size of the red sub-pixels 12 in the second pixels P2 and the size of the green sub-pixels in the second pixels P2 are smaller than that of the second blue sub-pixels 11 in the second pixels P2. Since blue sub-pixels have low luminous efficiency and relatively short lifetime, the first blue sub-pixels 10 and the second blue sub-pixels 11 are set to be longer or wider, the size of the first blue sub-pixels 10 and the size of the second blue sub-pixels 11 are increased and the service life of the first blue sub-pixels 10 and the service life of the second blue sub-pixels 11 can be prolonged, which is conducive to balancing the service life between sub-pixels.

In the embodiments of the present disclosure, the shapes of the first blue sub-pixels 10, the second blue sub-pixels 11, the red sub-pixels 12, and the green sub-pixels 13 may be simple squares or rectangles, which are not limited here.

When the display panel is in the regular display mode, the first blue sub-pixels 10 and the second blue sub-pixels 11 are driven to perform image display; when the display panel is in the eye protection display mode, the second blue sub-pixels 11 are driven to perform image display, and the user can freely adjust the display mode according to the use requirements.

The above-described display panel provided in the embodiments of the present disclosure is an organic light-emitting diode display panel, which has advantages of high color saturation, light weight, thinness, and flexibility. Wherein, each of the sub-pixel units in the organic light-emitting diode display panel can employ an organic light-emitting diode device, the shape of each sub-pixel can be designed by an etching process, and the pattern of the light-emitting layer can be formed by a process such as evaporation, so as to form any one of the pixel arrangement structures described above.

Based on the same inventive concept, an embodiment of the present disclosure also provides a display device, including the display panel provided by any one of the embodiments described above. Since the principle of solving the problem of the display device is similar to that of the above-described display panel, the implementation of the display device can refer to the implementation of the above display panel, and the repetition will not be repeated.

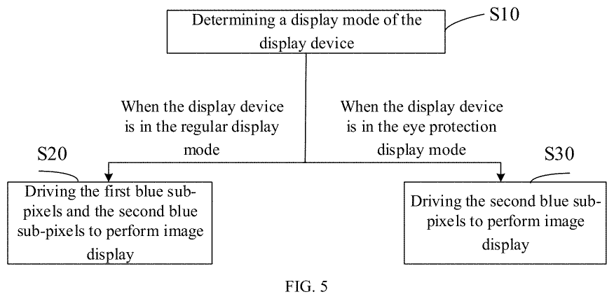

In another aspect of the embodiments of the present disclosure, a control method of the display device is provided. FIG. 5 is a flow diagram of a control method of a display device provided by an embodiment of the present disclosure.

Referring to FIG. 5, the control method of the display device provided by the embodiment of the present disclosure includes the following.

S10, a display mode of the display device is determined; a step S20 is performed when the display device is in the regular display mode, and a step S30 is performed when the display device is in the eye protection display mode.

S20, the first blue sub-pixels and the second blue sub-pixels are driven to perform image display.

S30, the second blue sub-pixels are driven to perform image display.

In some embodiments, firstly, the display mode of the display device is determined; when the display panel is in the regular display mode, the first blue sub-pixels and the second blue sub-pixels are driven to perform image display; when the display panel is in the eye protection display mode, the second blue sub-pixels are driven to perform image display.

Since the wavelength of each second blue sub-pixel is greater than the wavelength of each first blue sub-pixel, when the display panel is in the regular display mode, simultaneously driving the first blue sub-pixels and the second blue sub-pixels to perform image display can increase the saturation of blue color. When the display panel is in the eye protection display mode, and only the second blue sub-pixels that are non-irritating to the human eyes are driven to perform image display, eye fatigue can be mitigated. The user can freely switch the display modes according to the use requirements.

Since the first blue sub-pixels and the second blue sub-pixels emit light simultaneously in the regular display mode, while only the second blue sub-pixels emit light in the eye protection display mode, in order to make the display brightness difference between the two display modes be within the preset range, the display brightness of each second blue sub-pixel in the eye protection display mode is set to be greater than the display brightness of the second blue sub-pixel in the regular display mode in the embodiments of the present disclosure.

Further, in a practical application, the number of the first blue sub-pixels provided by the embodiments of the present disclosure and the number of the second blue sub-pixels provided by the embodiments of the present disclosure are equal, at this time, the display brightness of each second blue sub-pixel in the eye protection display mode may be set to be 2 times the display brightness of the second blue sub-pixel in the regular display mode, so as to ensure that the display brightness of the display device in the eye protection display mode is the same as the display brightness of the display device in the regular display mode.

According to the display panel, the display device, and the control method of the display device provided by the present disclosure, the display panel includes the sub-pixels of the plurality of colors, wherein the sub-pixels of the plurality of colors include the first blue sub-pixels and the second blue sub-pixels, and the wavelength of each first blue sub-pixel is smaller than the wavelength of each second blue sub-pixel. When the first blue sub-pixels are used for image display, the blue saturation of the display screen can be improved, and when the second blue sub-pixels are used for image display, the damage to human eyes can be avoided. Thus, the first blue sub-pixels and the second blue sub-pixels are driven to perform image display when the display panel is in the regular display mode; and the second blue sub-pixels are driven to perform image display when the display panel is in the eye protection display mode. Since the wavelength of each second blue sub-pixel is greater than the wavelength of each first blue sub-pixel, when the display panel is in the regular display mode, simultaneously driving the first blue sub-pixels and the second blue sub-pixels to perform image display can increase the saturation of blue color. When the display panel is in the eye protection display mode, and only the second blue sub-pixels that are non-irritating to the human eyes are driven to perform image display, eye fatigue can be mitigated. The user can freely switch the display modes according to the use requirements.

While the preferred embodiments of the present disclosure have been described, additional changes and modifications may be made to these embodiments once the basic inventive concepts are known to those skilled in the art. Therefore, the appended claims are intended to be interpreted as including preferred embodiments and all changes and modifications falling within the scope of the present disclosure.

Obviously, those skilled in the art can make various changes and modifications to the present disclosure without departing from the spirit and scope of the present disclosure. Thus, if these changes and modifications of the present disclosure fall within the scope of the claims of the present disclosure and its equivalent technology, the present disclosure is also intended to include these changes and modifications.

What is claimed is:

1. A display panel, comprising: sub-pixels of a plurality of colors; wherein:
the sub-pixels of the plurality of colors comprise first blue sub-pixels and second blue sub-pixels; and a wavelength of each of the first blue sub-pixels is smaller than a wavelength of each of the second blue sub-pixels;
the first blue sub-pixels and the second blue sub-pixels are driven to perform image display when the display panel is in a regular display mode; and
the second blue sub-pixels are driven to perform image display when the display panel is in an eye protection display mode.

2. The display panel according to claim 1, wherein the wavelength of the first blue sub-pixel is 440-455 nm and the wavelength of the second blue sub-pixel is 455-480 nm.

3. The display panel according to claim 1, wherein a display brightness of the second blue sub-pixel in the eye protection display mode is greater than a display brightness of the second blue sub-pixel in the regular display mode.

4. The display panel according to claim 3, wherein the display brightness of the second blue sub-pixel in the eye protection display mode is 2 times the display brightness of the second blue sub-pixel in the regular display mode.

5. The display panel according to claim 1, wherein the sub-pixels of the plurality of colors further comprise: red sub-pixels and green sub-pixels.

6. The display panel according to claim 5, wherein the first blue sub-pixels and the red sub-pixels are alternately arranged in a first direction to form first pixel rows; the second blue sub-pixels and the red sub-pixels are alternately arranged in the first direction to form second pixel rows; the first pixel rows and the second pixel rows are alternately arranged in a second direction; and the first direction and the second direction intersect;
the first blue sub-pixels and the red sub-pixels are alternately arranged in the second direction to form first pixel columns; the second blue sub-pixels and the red sub-pixels are alternately arranged in the second direction to form second pixel columns; and the first pixel columns and the second pixel columns are alternately arranged in the first direction; and
one green sub-pixel is at a center of a quadrilateral formed by four sub-pixels in two adjacent rows and two adjacent columns.

7. The display panel according to claim 6, wherein each of the first blue sub-pixels and each of the second blue sub-pixels are the same in shape and size, an area of each of the red sub-pixels is smaller than an area of the first blue sub-pixel, and an area of each of the green sub-pixels is the smallest.

8. The display panel according to claim 6, wherein a shape of each of the first blue sub-pixels, the second blue sub-pixels, the red sub-pixels and the green sub-pixels is a square, a rectangle, a diamond, or a circle.

9. The display panel according to claim 5, wherein the first blue sub-pixels and the second blue sub-pixels are alternately arranged in a first direction to form a plurality of pixel rows; the first blue sub-pixels and the second blue sub-pixels are alternately arranged in a second direction to form a plurality of pixel columns; and the first direction and the second direction intersect;
in each of the pixel rows, one red sub-pixel is between a first blue sub-pixel and a second blue sub-pixel adjacent to each other; and in each of the pixel columns, one red sub-pixel is between a first blue sub-pixel and a second blue sub-pixel adjacent to each other; and
one green sub-pixel is at a center of a quadrilateral formed by four sub-pixels in two adjacent rows and two adjacent columns.

10. The display panel according to claim 9, wherein each of the first blue sub-pixels and each of the second blue sub-pixels are the same in shape and size, an area of each of the red sub-pixels is smaller than an area of the first blue sub-pixel, and an area of each of the green sub-pixels is the smallest.

11. The display panel according to claim 9, wherein a shape of each of the first blue sub-pixels, the second blue sub-pixels, the red sub-pixels and the green sub-pixels is a square, a rectangle, a diamond, or a circle.

12. The display panel according to claim 5, wherein one red sub-pixel, one green sub-pixel, and one first blue sub-pixel constitute a first pixel; and one red sub-pixel, one green sub-pixel, and one second blue sub-pixel constitute a second pixel; and
first pixels and second pixels are alternately arranged in a first direction, and the first pixels and the second pixels are alternately arranged in a second direction; and the first direction and the second direction intersect.

13. The display panel according to claim 12, wherein the first blue sub-pixels, the second blue sub-pixels, the red sub-pixels, and the green sub-pixels are the same in size.

14. The display panel according to claim 5, wherein one red sub-pixel, one green sub-pixel, and one first blue sub-pixel constitute a first pixel; and the one green sub-pixel and the one red sub-pixel in the first pixel are arranged along one side of the first blue sub-pixel in the first pixel;
one red sub-pixel, one green sub-pixel, and one second blue sub-pixel constitute a second pixel; and the one green sub-pixel and the one red sub-pixel in the second pixel are arranged along one side of the second blue sub-pixel in the second pixel; and
first pixels and second pixels are alternately arranged in a first direction, and the first pixels and the second pixels are alternately arranged in a second direction; and the first direction and the second direction intersect.

15. The display panel according to claim 14, wherein a size of the first blue sub-pixel and a size of the second blue sub-pixel are the same, a size of the red sub-pixel in the first pixel and a size of the green sub-pixel in the first pixel are smaller than the size of the first blue sub-pixel in the first pixel, and a size of the red sub-pixel in the second pixel and a size of the green sub-pixel in the second pixel are smaller than the size of the second blue sub-pixel in the second pixel.

16. The display panel according to claim 1, wherein the display panel is an organic light-emitting diode display panel.

17. A display device, comprising the display panel according to claim 1.

18. A control method of a display device, wherein the display device is according to claim 17, and the control method comprises:
driving the first blue sub-pixels and the second blue sub-pixels to perform image display when the display device is in a regular display mode; and
driving the second blue sub-pixels to perform image display when the display device is in an eye protection display mode.

19. The control method according to claim 18, wherein a display brightness of the second blue sub-pixel in the eye protection display mode is greater than a display brightness of the second blue sub-pixel in the regular display mode.

20. The control method according to claim 19, wherein the display brightness of the second blue sub-pixel in the eye protection display mode is 2 times the display brightness of the second blue sub-pixel in the regular display mode.
